(19) United States
(12) Patent Application Publication
(10) Pub. No.: US 2026/0243713 A1
(43) Pub. Date: Aug. 20, 2026

(54) Determination of Critical Gas Saturation

(71) Applicant: Chevron U.S.A. Inc., San Ramon, CA (US)

(72) Inventors: Michael Thomas Rauschhuber, Houston, TX (US); Josephina Maria Schembre-McCabe, Houston, TX (US)

(21) Appl. No.: 19/540,672

(22) Filed: Feb. 14, 2026

Related U.S. Application Data
(60) Provisional application No. 63/758,499, filed on Feb. 14, 2025.

(51) Int. Cl. G01N 24/08

(52) U.S. Cl. CPC G01N 24/081; G01N 24/082

(57) ABSTRACT

A system of performing a test, such as critical gas saturation, for a core sample is described. The system comprises a magnetic resonance apparatus comprising a gradient set configured to image a core sample and a probe configured to control a temperature within a core holder. The probe is positioned within the gradient set, and the core holder is positioned within the probe. The system comprises the core holder configured to receive the core sample and a saturation fluid, the core holder being compatible with the magnetic resonance apparatus and configured to be positioned within the probe. The system comprises an upstream injecting system to inject the saturation fluid into the core holder to saturate the core sample and a downstream receiving system to control a pressure within the core holder and receive at least a portion of the saturation fluid exiting the core holder.

### CROSS-REFERENCE TO RELATED APPLICATIONS

This application claims priority to U.S. provisional application No. 63/758,499, filed on Feb. 14, 2025, the entire disclosure of which is incorporated herein by reference.

### STATEMENT REGARDING FEDERALLY SPONSORED RESEARCH OR DEVELOPMENT

Not applicable.

### TECHNICAL FIELD

The disclosed embodiments relate generally to techniques of performing a test on a core sample, such as a test to determine critical gas saturation for a core sample.

### BACKGROUND

Critical gas saturation is a key parameter for reservoir performance in certain circumstances. Indeed, critical gas saturation is of significant economic concern during the development and life of the reservoir. However, it is challenging to determine critical gas saturation for some core samples, such as unconventional shale core samples and tight carbonate core samples, using traditional methodologies.

### SUMMARY

In accordance with some embodiments, a system of performing a test on a core sample is disclosed herein. The system comprises a magnetic resonance apparatus comprising a gradient set configured to image a core sample and a probe configured to control a temperature within a core holder. The probe is positioned within the gradient set, and the core holder is positioned within the probe. The system comprises the core holder configured to receive the core sample and a saturation fluid, the core holder being compatible with the magnetic resonance apparatus and configured to be positioned within the probe. The system comprises an upstream injecting system fluidly coupled to an inlet of the core holder and configured to inject the saturation fluid into the core holder to saturate the core sample. The system comprises a downstream receiving system fluidly coupled to an outlet of the core holder and configured to control a pressure within the core holder and receive at least a portion of the saturation fluid exiting the core holder.

In accordance with some embodiments, a method of determining critical gas saturation for a core sample is disclosed herein. The method comprises (a) mounting a core sample within a core holder in a system. The system comprises a magnetic resonance apparatus comprising a gradient set configured to image the core sample and a probe configured to control a temperature within the core holder. The probe is positioned within the gradient set, and the core holder is positioned within the probe. The system comprises the core holder configured to receive the core sample and a saturation fluid, the core holder being compatible with the magnetic resonance apparatus and configured to be positioned within the probe. The system comprises an upstream injecting system fluidly coupled to an inlet of the core holder and configured to inject the saturation fluid into the core holder to saturate the core sample. The system comprises a downstream receiving system fluidly coupled to an outlet of the core holder and configured to control a pressure within the core holder and receive at least a portion of the saturation fluid exiting the core holder. The method comprises (b) inserting the core holder containing the core sample within the probe of the magnetic resonance apparatus. The method comprises (c) injecting at least one saturation fluid within the core holder to saturate the core sample within the core holder. The method comprises (d) performing a controlled pressure change of the core sample using the downstream receiving system. The method comprises (e) collecting magnetic resonance data for the core sample during the controlled pressure change. The method comprises (f) determining the critical gas saturation from the magnetic resonance data for the core sample.

### BRIEF DESCRIPTION OF THE DRAWINGS

FIG. 1A illustrates one embodiment of a system for performing a test on a core sample. In one embodiment, the test comprises determining critical gas saturation for the core sample.

FIG. 1B illustrates the system of FIG. 1A with an alternative downstream receiving system.

FIG. 1C illustrates an end view of a magnetic resonance apparatus of FIG. 1A and FIG. 1B.

FIG. 1D illustrates a side view of the magnetic resonance apparatus of FIG. 1A, FIG. 1B, and FIG. 1C.

FIG. 2 illustrates one embodiment of a computer of FIG. 1A and FIG. 1B.

FIG. 3 illustrates one embodiment of a method of determining critical gas saturation for a core sample.

FIGS. 4A-4F illustrate T₁-T₂ relaxation time distributions collected throughout the controlled pressure depletion the unconventional share core sample in the running example herein.

FIG. 5 illustrates NMR volumes calculated from the controlled pressure depletion for the unconventional shale core sample in the running example herein.

FIG. 6 also illustrates magnetic resonance data collected for the unconventional share core sample in the running example herein.

FIG. 7 illustrates changes in pressure drop.

FIG. 8 illustrates the produced oil and gas volumes utilizing Option #2.

FIG. 9 demonstrates the differential pressure during the controlled pressure depletion depicted in FIGS. 4A-4F and Equation 306.

Like reference numerals refer to corresponding parts throughout the drawings.

### DETAILED DESCRIPTION OF EMBODIMENTS

Critical gas saturation, also referred to as Sgc, is a key parameter for reservoir performance in certain circumstances. Indeed, critical gas saturation is of significant economic concern during the development and life of the reservoir.

However, it is challenging to determine critical gas saturation for some core samples, such as unconventional shale core samples and tight carbonate core samples using traditional methodologies. Currently, laboratory measurements include lab-scale pressure depletion tests or external gas drive corefloods. Coreflood units may be equipped with pumps, core holders, and CT-scanners to detect the movement of gas in the porous core sample. Units without CT-scanners have reduced accuracy in the measurement of fluid saturations relying on material balances of injected and produced fluids. While the addition of a CT-scanner improves saturation determination, performance suffers when analyzing core samples with lower porosity and permeability, and subsequently smaller pore sizes. Other techniques include the use of micro-CT, which allow measurement of gas bubbles forming and connecting within Bentheimer sandstone. Unfortunately, these techniques are sometimes poor quantifiers of saturations in some core samples, such as unconventional shale core samples and tight carbonate core samples.

In contrast, in accordance with some embodiments, a system of performing a test on a core sample is disclosed herein. The system comprises a magnetic resonance apparatus comprising a gradient set configured to image a core sample and a probe configured to control a temperature within a core holder. The probe is positioned within the gradient set, and the core holder is positioned within the probe. The system comprises the core holder configured to receive the core sample and a saturation fluid, the core holder being compatible with the magnetic resonance apparatus and configured to be positioned within the probe. The system comprises an upstream injecting system fluidly coupled to an inlet of the core holder and configured to inject the saturation fluid into the core holder to saturate the core sample. The system comprises a downstream receiving system fluidly coupled to an outlet of the core holder and configured to control a pressure within the core holder and receive at least a portion of the saturation fluid exiting the core holder.

Moreover, in accordance with some embodiments, a method of determining critical gas saturation for a core sample is disclosed herein. The method comprises (a) mounting a core sample within a core holder in a system. The system comprises a magnetic resonance apparatus comprising a gradient set configured to image the core sample and a probe configured to control a temperature within the core holder. The probe is positioned within the gradient set, and the core holder is positioned within the probe. The system comprises the core holder configured to receive the core sample and a saturation fluid, the core holder being compatible with the magnetic resonance apparatus and configured to be positioned within the probe. The system comprises an upstream injecting system fluidly coupled to an inlet of the core holder and configured to inject the saturation fluid into the core holder to saturate the core sample. The system comprises a downstream receiving system fluidly coupled to an outlet of the core holder and configured to control a pressure within the core holder and receive at least a portion of the saturation fluid exiting the core holder. The method comprises (b) inserting the core holder containing the core sample within the probe of the magnetic resonance apparatus. The method comprises (c) injecting at least one saturation fluid within the core holder to saturate the core sample within the core holder. The method comprises (d) performing a controlled pressure change of the core sample using the downstream receiving system. The method comprises (e) collecting magnetic resonance data for the core sample during the controlled pressure change. The method comprises (f) determining the critical gas saturation from the magnetic resonance data for the core sample.

Critical gas saturation is defined as the volume fraction at which gas becomes connected and mobile with in a reservoir. For an oil reservoir undergoing primary depletion, solution is a primary recovery mechanism. Below the critical gas saturation, gas bubbles are trapped but their expansion during depletion help to drive oil from the reservoir and stabilize pressure. Once critical gas saturation has been reached, gas flow increases dramatically and will dominate production. Additionally, depletion rate is a key factor that has a direct impact on critical gas saturation. Generally, faster depletion rates yield large critical gas saturations resulting in greater oil recoveries. Therefore, knowledge of critical gas saturation, and the impact of depletion rate on it, greatly influence reservoir drawdown and pressure maintenance strategies as well as economic evaluation for the field.

For instance, with more accurate estimates of critical gas saturation supplemented to relative permeability relationships for reservoir simulation, reliability of production forecast for oil fields undergoing solution gas drive increases, and economic uncertainty surrounding investment decisions regarding gas production and field development reduces.

As provided in this document, integration of NMR and/or MRI with laboratory-scale pressure depletion may increase the accuracy of estimates of critical gas saturations for core samples, such as unconventional shale core samples and tight carbonate core samples. The accuracy of estimates of critical gas saturations may even be increased for core samples that are not unconventional shale core samples and not tight carbonate core samples.

Indeed, as provided in this document, a system integrated with nuclear magnetic resonance (NMR) and/or magnetic resonance Imaging (MRI) was developed for determining critical gas saturation for core samples. This system may allow for in-situ NMR and MRI measurements at reservoir-like conditions. The MRI may detect 1H content within the core sample under study, and through analysis of NMR properties such as initial magnetization (Mₒ), spin-lattice relaxation (T₁), spin-spin relaxation time (T₂), and the self-diffusion coefficient (D), identifies pore volumes occupied by the different phases (water, oil, gas). For instance, critical gas saturation may be a key parameter for reservoir performance for reservoirs under solution gas drive and its dependency on the drawdown rate during production.

Critical gas saturation is of significant economic concern during the development and life of the reservoir. The ability to determine critical gas saturation, especially for core samples, such as unconventional shale core samples and tight carbonate core samples, is crucial to our ability to make the most appropriate choices for determining when to add gas processing equipment in the surface facility, determining sizing of the gas processing equipment to add to the surface facility, determining drawdown rate to set for the reservoir, depletion planning to impact production from the reservoir, production forecasting to forecast hydrocarbon recovery, etc.

Reference will now be made in detail to various embodiments, examples of which are illustrated in the accompanying drawings. In the following detailed description, numerous specific details are set forth in order to provide a thorough understanding of the present disclosure and the embodiments described herein. However, embodiments described herein may be practiced without these specific details. In other instances, well-known methods, procedures, components, and mechanical apparatus have not been described in detail so as not to unnecessarily obscure aspects of the embodiments.

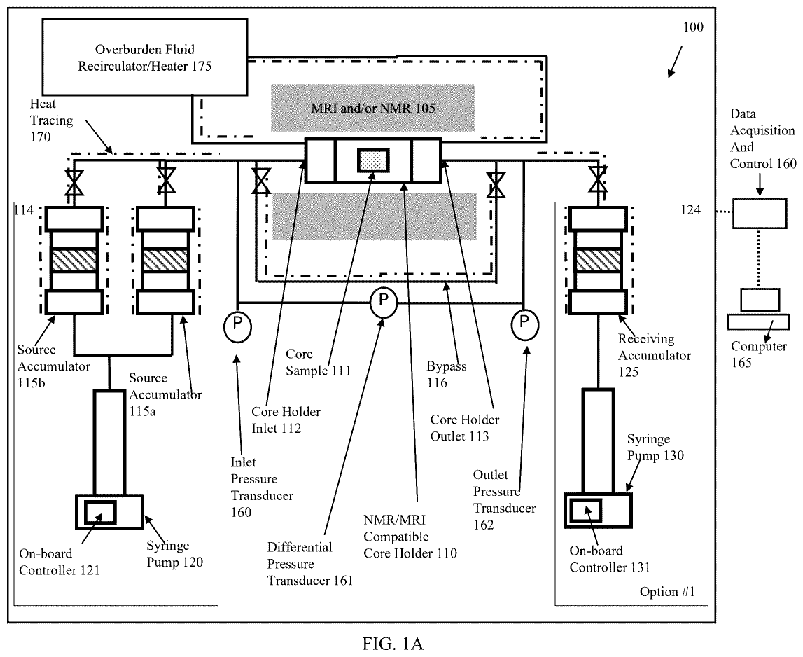

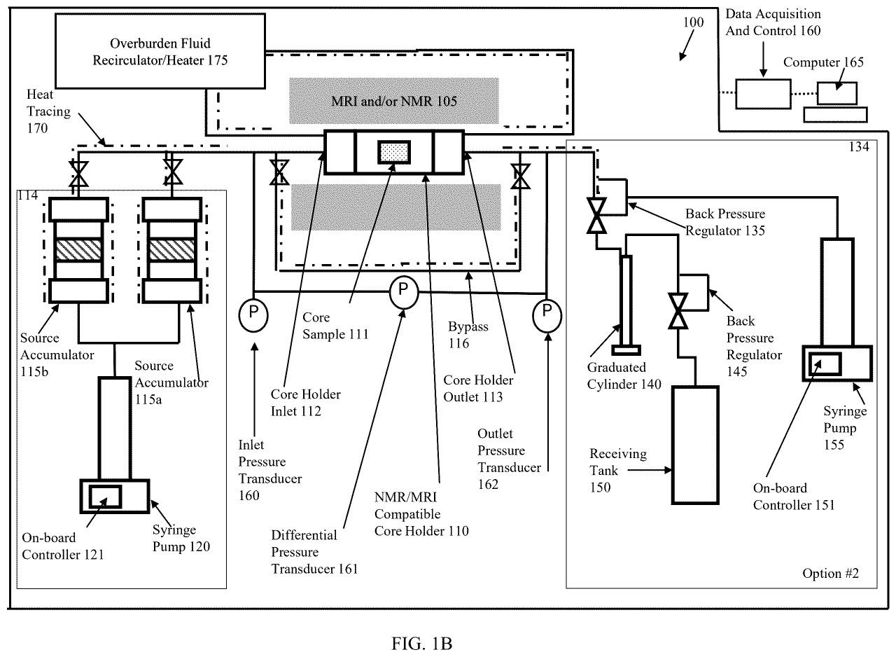

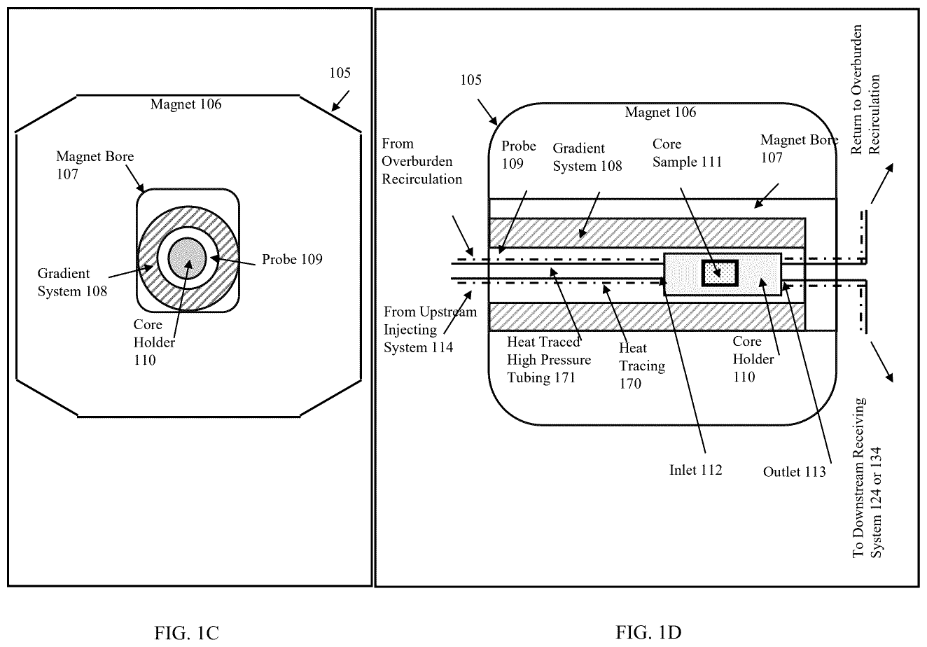

Turning to the figures, FIG. 1A illustrates one embodiment of a system for performing a test on a core sample. In one embodiment, the test comprises determining critical gas saturation for the core sample. FIG. 1B illustrates the system of FIG. 1A with an alternative downstream receiving system. FIG. 1C illustrates an end view of a magnetic resonance apparatus of FIG. 1A and FIG. 1B. FIG. 1D illustrates a side view of the magnetic resonance apparatus of FIG. 1A, FIG. 1B, and FIG. 1C. These figures will be discussed in more detail below.

A system 100 is provided herein for performing a test on a core sample 111. In one embodiment, the test comprises determining critical gas saturation for the core sample 111. The system 100 comprises a magnetic resonance apparatus 105. In one embodiment, the magnetic resonance apparatus 105 comprises magnetic resonance imaging (MRI), such as, but not limited to, MRI configured to operate at about 42 MHz. In one embodiment, the magnetic resonance apparatus 105 comprises nuclear magnetic resonance (NMR). In one embodiment, the magnetic resonance apparatus 105 comprises both magnetic resonance imaging (MRI) and nuclear magnetic resonance (NMR). As illustrated in FIGS. 1C-1D, the magnetic resonance apparatus 105 may comprise at least one magnet 106 as well as a magnet bore 107.

The magnetic resonance apparatus 105 comprises a gradient system 108 configured to image the core sample 111. The gradient system 108 may comprise at least one gradient coil, such as three gradient coils for MRI. The gradient system 108 may not have any gradient coils for NMR. If the gradient system 108 comprises one or more gradient coils, then the gradient system 108 may also comprise a cooling system for cooling. As illustrated in FIGS. 1C-1D, the gradient system 108 may be cylindrical in shape and positioned within the magnet bore 107.

The magnetic resonance apparatus 105 also comprises a probe 109 configured to control temperature within a core holder 110. As illustrated in FIGS. 1C-1D, the probe 109 may be cylindrical in shape and positioned within the gradient system 108.

In some embodiments, the probe 109 provides a temperature within the core holder 110 of at least 68° F. (e.g., at least 69° F., at least 70° F., at least 71° F., at least 72° F., at least 73° F., at least 74° F., at least 75° F., at least 76° F., at least 77° F., at least 78° F., at least 79° F., at least 80° F., at least 90° F., at least 100° F., at least 110° F., at least 120° F., at least 130° F., at least 140° F., at least 150° F., at least 160° F., at least 170° F., at least 180° F., at least 190° F., at least 200° F., at least 210° F., at least 220° F., at least 230° F., at least 240° F., at least 250° F., at least 260° F., at least 270° F., at least 280° F., or at least 290° F.). In some embodiments, the probe 109 provides a temperature within the core holder 110 of 300° F. or less (e.g., 290° F. or less, 280° F. or less, 270° F. or less, 260° F. or less, 250° F. or less, 240° F. or less, 230° F. or less, 220° F. or less, 210° F. or less, 200° F. or less, 190° F. or less, 180° F. or less, 170° F. or less, 160° F. or less, 150° F. or less, 140° F. or less, 130° F. or less, 120° F. or less, 110° F. or less, 100° F. or less, 90° F. or less, 80° F. or less, 79° F. or less, 78° F. or less, 77° F. or less, 76° F. or less, 75° F. or less, 74° F. or less, 73° F. or less, 72° F. or less, 71° F. or less, 70° F. or less, or 69° F. or less).

The probe 109 provides a temperature within the core holder 110 ranging from any of the minimum values described above to any of the maximum values described above. For example, in some embodiments, the probe 109 provides a temperature within the core holder 110 of from 68° F. to 300° F. (e.g., from 68° F. to 250° F., from 68° F. to 210° F., from 68° F. to 150° F., from 68° F. to 100° F., from 210° F. to 225° F., from 210° F. to 250° F., from 210° F. to 275° F., from 210° F. to 300° F., from 225° F. to 300° F., from 225° F. to 250° F., from 250° F. to 300° F., from 275° F. to 300° F., or from 210° F. to 290° F.). For example, in some embodiments, the probe 109 provides a temperature within the core holder 110 of from room temperature to 300° F.

The system 100 comprises the core holder 110 configured to receive the core sample 111 and at least one saturation fluid. In one embodiment, a saturation fluid comprises a dead oil (e.g., hydrocarbon liquid void of dissolved gas), such as decane or stock tank oil. In one embodiment, a saturation fluid comprises a live oil (e.g., hydrocarbon liquid with dissolved gas).

In one embodiment, the core holder 110 is compatible with the magnetic resonance apparatus 105, such as, compatible with MRI. In one embodiment, the core holder 110 is compatible with the magnetic resonance apparatus 105, such as, compatible with NMR. In one embodiment, the core holder 110 is compatible with the magnetic resonance apparatus 105, such as, compatible with both MRI and NMR. The core holder 110 is constructed of non-magnetic materials, such as zirconia, to enable operation within the MRI and/or NMR magnet bore 107. As illustrated in FIGS. 1C-1D, the core holder 110 may be cylindrical in shape and positioned within the probe 109. Indeed, FIG. 1C illustrates an end view of the magnetic resonance apparatus 105 (MRI and/or NMR) including the magnet 106 defining the magnet bore 107, within which the core holder 110 containing the core sample 111 is positioned. The probe 109 and the gradient system 108 are arranged around the core holder 110 inside the magnet bore 107 to enable NMR or MRI measurements of the core sample 111 during operation.

The system 100 comprises an upstream injecting system 114 fluidly coupled to an inlet 112 of the core holder 110. The upstream injecting system 114 is configured to inject at least one saturation fluid into the core holder 110 to saturate the core sample 111 within the core holder 110. The upstream injecting system 114 comprises at least one source accumulator 115, such as at least one floating piston accumulator. Each source accumulator 115 is configured to store at least one saturation fluid. The upstream injecting system 114 comprises at least one syringe pump 120. The syringe pump 120 is fluidly coupled to each source accumulator 115 and configured control each source accumulator 115 to inject the selected saturation fluid into the core holder 110. The syringe pump 120 may be a dual barrel continuous flow syringe pump fluidly coupled to each source accumulator 115. For instance, the hydraulic side of each source accumulators 115 may be driven by the dual barrel, continuous flow syringe pump 120. The syringe pump 120 may be controlled by a controller, such as an on-board controller 121. The on-board controller 121 may be utilized to select operating parameters for the syringe pump 120, such as selecting a continuous mode of operation for the syringe pump 120, selecting which source accumulator 115 (e.g., source accumulators 115a vs 115b) and its corresponding saturation fluid to inject into the core holder 110, etc. Of note, the upstream injecting system 114 in FIGS. 1A-1B is not meant to be limiting and variations are possible, such as a different quantity of source accumulators (e.g., a single source accumulator 115), a different quantity of syringe pumps, etc.

The system 100 comprises a downstream receiving system fluidly coupled to an outlet 113 of the core holder 110. The downstream receiving system is configured to control pressure within the core holder 110. The downstream receiving system is also configured to receive at least a portion of the saturation fluid(s) existing the core holder 110. Two alternatives, Option #1 and Option #2, are provided hereinbelow for the downstream receiving system.

As illustrated in FIG. 1A, a downstream receiving system 124 (Option #1) comprises at least one receiving accumulator 125, such as at least one floating piston accumulator. Each receiving accumulator 125 is configured to receive at least a portion of the saturation fluid(s) exiting the core holder 110. The downstream receiving system 124 comprises at least one syringe pump 130. The syringe pump 130 is fluidly coupled to each receiving accumulator 125 and configured to control each coupled receiving accumulator 125 to receive the saturation fluid(s) exiting the core holder 110. The syringe pump 130 may be a dual barrel continuous flow syringe pump fluidly coupled to each receiving accumulator 125. For instance, the hydraulic side of each receiving accumulator 125 is driven by the dual barrel, continuous flow syringe pump 120. The syringe pump 130 may be controlled by a controller, such as an on-board controller 131. The on-board controller 131 may be utilized to select operating parameters for the syringe pump 130, such as selecting a continuous mode of operation for the syringe pump 130. For Option #1, a computer 165 (e.g., a PC) and an external controller (e.g., data acquisition and control 160) may be utilized by a user to send updates to the syringe pump 130 and its on-board controller 131 to manage pressure change (e.g., pressure decline) during a critical gas saturation test and/or pressure depletion test. A test (e.g., a critical gas saturation test) may last multiple days to multiple months, and the downstream receiving system 124 is utilized to control pressure within the core holder 110 during the test. Of note, the downstream receiving system 124 in FIG. 1A is not meant to be limiting and variations are possible, such as a different quantity of receiving accumulators, a different quantity of syringe pumps, etc.

As illustrated in FIG. 1B, a downstream receiving system 134 (Option #2) may function as a separator allowing for the determination of a gas-oil ratio (GOR). Pressure is maintained in the core sample 110 utilizing at least one back pressure regulator 135, such as at least one high-pressure back pressure regulator 135. The saturation fluid(s) flow from the core holder 110 through the back pressure regulator 135 and flash into at least one graduated cylinder 140 allowing for gas and oil to separate. Pressure in the graduated cylinder 140 is maintained using at least one back pressure regulator 145, such as at least one low-pressure back pressure regulator 145. Gas is collected in at least one receiving tank/vessel 150. Pressure in the low-pressure back pressure regulator 145 may be maintained near atmospheric pressure. The downstream receiving system 134 may comprise at least one syringe pump 155. The syringe pump 155 may be a dual barrel continuous flow syringe pump fluidly coupled to at least one back pressure regulator, such as the high-pressure back pressure regulator 135. The syringe pump 155 may comprise an on-board controller 151 for selecting operating parameters for the syringe pump 155, such as selecting a continuous mode of operation for the syringe pump 155. As illustrated in FIG. 1B, the dual barrel, continuous flow syringe pump 155 may control the high-pressure back pressure regulator 135. For Option #2, the computer 165 (e.g., a PC) and the external controller (e.g., data acquisition and control 160) may be utilized by a user to send updates to the syringe pump 155 and its on-board controller 151 to manage pressure change (e.g., pressure decline) during a critical gas saturation test and/or pressure depletion test. For instance, the computer 165 and the external controller (e.g., data acquisition and control 160) may be utilized to manage the pressure for the high-pressure back pressure regulator 135. A test (e.g., a critical gas saturation test) may last multiple days to multiple months, and the downstream receiving system 134 is utilized to control pressure within the core holder 110 during the test. Of note, the downstream receiving system 134 in FIG. 1B is not meant to be limiting and variations are possible, such as a different quantity of high-pressure back pressure regulators, a different quantity of low-pressure back pressure regulators, a different quantity of syringe pumps, etc.

In other words, for Option #2, the downstream receiving system 134 comprises: a high-pressure back pressure regulator fluidly coupled to the outlet of the core holder and configured to receive the portion of the saturation fluid exiting the core holder; a cylinder fluidly coupled to the high-pressure back pressure regulator to receive the portion of the saturation fluid exiting the core holder and configured for gas and oil separation, wherein the oil from the portion of the saturation fluid exiting the core holder remains in the cylinder after separation; a low-pressure back pressure regulator fluidly coupled to the cylinder to receive gas from the portion of the saturation fluid exiting the core holder after separation and configured to control pressure in the cylinder; a receiving tank fluidly coupled to the low-pressure back pressure regulator to receive the gas from the portion of the saturation fluid exiting the core holder after separation; a syringe pump fluidly coupled to the high-pressure back pressure regulator and configured to control the coupled the high-pressure back pressure regulator; and an on-board controller configured to control the syringe pump.

The downstream receiving system (i.e., system 124 and system 134) is configured to control pressure within the core holder 110. In some embodiments, the downstream receiving system (i.e., system 124 and system 134) provides pressure within the core holder 110 of at least 200 PSI (e.g., at least 300 PSI, at least 400 PSI, at least 500 PSI, at least 600 PSI, at least 700 PSI, at least 800 PSI, at least 900 PSI, at least 1,000 PSI, at least 1,100 PSI, at least 1,200 PSI, at least 1,300 PSI, at least 1,400 PSI, at least 1,500 PSI, at least 1,600 PSI, at least 1,700 PSI, at least 1,800 PSI, at least 1,900 PSI, at least 2,000 PSI, at least 2,100 PSI, at least 2,200 PSI, at least 2,300 PSI, at least 2,400 PSI, at least 2,500 PSI, at least 2,600 PSI, at least 2,700 PSI, at least 2,800 PSI, at least 2,900 PSI, at least 3,000 PSI, at least 3,100 PSI, at least 3,200 PSI, at least 3,300 PSI, at least 3,400 PSI, at least 3,500 PSI, at least 3,600 PSI, at least 3,700 PSI, at least 3,800 PSI, at least 3,900 PSI, at least 4,000 PSI, at least 4,100 PSI, at least 4,200 PSI, at least 4,300 PSI, at least 4,400 PSI, at least 4,500 PSI, at least 4,600 PSI, at least 4,700 PSI, at least 4,800 PSI, or at least 4,900 PSI, at least 5,000 PSI, at least 5,100 PSI, at least 5,200 PSI, at least 5,300 PSI, at least 5,400 PSI, at least 5,500 PSI, at least 5,600 PSI, at least 5,700 PSI, at least 5,800 PSI, at least 5,900 PSI, at least 6,000 PSI, at least 6,100 PSI, at least 6,200 PSI, at least 6,300 PSI, at least 6,400 PSI, at least 6,500 PSI, at least 6,600 PSI, at least 6,700 PSI, at least 6,800 PSI, at least 6,900 PSI, at least 7,000 PSI, at least 7,100 PSI, at least 7,200 PSI, at least 7,300 PSI, at least 7,400 PSI, at least 7,500 PSI, at least 7,600 PSI, at least 7,700 PSI, at least 7,800 PSI, at least 7,900 PSI, at least 8,000 PSI, at least 8,100 PSI, at least 8,200 PSI, at least 8,300 PSI, at least 8,400 PSI, at least 8,500 PSI, at least 8,600 PSI, at least 8,700 PSI, at least 8,800 PSI, at least 8,900 PSI, at least 9,000 PSI, at least 9,100 PSI, at least 9,200 PSI, at least 9,300 PSI, at least 9,400 PSI, at least 9,500 PSI, at least 9,600 PSI, at least 9,700 PSI, at least 9,800 PSI, or at least 9,900 PSI). In some embodiments, the downstream receiving system (i.e., system 124 and system 134) provides pressure within the core holder 110 of 10,000 PSI or less (e.g., 9,900 PSI or less, 9,800 PSI or less, 9,700 PSI or less, 9,600 PSI or less, 9,500 PSI or less, 9,400 PSI or less, 9,300 PSI or less, 9,200 PSI or less, 9,100 PSI or less, 9,000 PSI or less, 8,900 PSI or less, 8,800 PSI or less, 8,700 PSI or less, 8,600 PSI or less, 8,500 PSI or less, 8,400 PSI or less, 8,300 PSI or less, 8,200 PSI or less, 8,100 PSI or less, 8,000 PSI or less, 7,900 PSI or less, 7,800 PSI or less, 7,700 PSI or less, 7,600 PSI or less, 7,500 PSI or less, 7,400 PSI or less, 7,300 PSI or less, 7,200 PSI or less, 7,100 PSI or less, 7,000 PSI or less, 6,900 PSI or less, 6,800 PSI or less, 6,700 PSI or less, 6,600 PSI or less, 6,500 PSI or less, 6,400 PSI or less, 6,300 PSI or less, 6,200 PSI or less, 6,100 PSI or less, 6,000 PSI or less, 5,900 PSI or less, 5,800 PSI or less, 5,700 PSI or less, 5,600 PSI or less, 5,500 PSI or less, 5,400 PSI or less, 5,300 PSI or less, 5,200 PSI or less, 5,100 PSI or less, 5,000 PSI or less 4,900 PSI or less, 4,800 PSI or less, 4,700 PSI or less, 4,600 PSI or less, 4,500 PSI or less, 4,400 PSI or less, 4,300 PSI or less, 4,200 PSI or less, 4,100 PSI or less, 4,000 PSI or less, 3,900 PSI or less, 3,800 PSI or less, 3,700 PSI or less, 3,600 PSI or less, 3,500 PSI or less, 3,400 PSI or less, 3,300 PSI or less, 3,200 PSI or less, 3,100 PSI or less, 3,000 PSI or less, 2,900 PSI or less, 2,800 PSI or less, 2,700 PSI or less, 2,600 PSI or less, 2,500 PSI or less, 2,400 PSI or less, 2,300 PSI or less, 2,200 PSI or less, 2,100 PSI or less, 2,000 PSI or less, 1,900 PSI or less, 1,800 PSI or less, 1,700 PSI or less, 1,600 PSI or less, 1,500 PSI or less, 1,400 PSI or less, 1,300 PSI or less, 1,200 PSI or less, 1,100 PSI or less, 1,000 PSI or less, 900 PSI or less, 800 PSI or less, 700 PSI or less, 600 PSI or less, 500 PSI or less, 400 PSI or less, or 300 PSI or less).

The downstream receiving system (i.e., system 124 and system 134) provides pressure within the core holder 110 ranging from any of the minimum values described above to any of the maximum values described above. For example, in some embodiments, the downstream receiving system (i.e., system 124 and system 134) provides pressure within the core holder 110 of from 200 PSI to 10,000 PSI (e.g., from 200 PSI to 1,000 PSI, from 200 PSI to 2,000 PSI, from 200 PSI to 3,000 PSI, from 200 PSI to 4,000 PSI, from 200 PSI to 5,000 PSI, from 200 PSI to 2,500 PSI, from 1,000 PSI to 4,000 PSI, from 2,500 PSI to 5,000 PSI, or from 500 PSI to 3,000 PSI).

The system 100 may also be heated, if necessary, using temperature controllers, heating mantles, a heated overburden recirculation unit, etc. Pressure and temperature capabilities may be 200 PSI to 10,000 PSI and 68° F. to 300° F., respectively. As illustrated in FIGS. 1A, 1B, and 1D, the system 100 may comprise additional components related to temperature, such as, but not limited to, heat tracing 170, heat traced high pressure tubing 171, and/or overburden fluid recirculatory/heater 175. For instance, the heat tracing 170, heat traced high pressure tubing 171, and/or the overburden fluid recirculatory/heater 175 may be utilized with components of the system 100, such as, but not limited to, each source accumulator 115, each receiving accumulator 125, the magnetic resonance apparatus 105, the core holder 110, valves (illustrated as bow ties in FIGS. 1A-1B), and bypass 116. FIG. 1D illustrates a side view of a portion of the system 100 illustrating the core holder 110 positioned within the magnet bore 107 of the magnet 106, with the probe 109 and gradient system 108 arranged around the core sample 111. The FIG. 1D further illustrates heat traced high pressure tubing 171 fluidly coupled to the core holder 110, including connections to the upstream injecting system 114, overburden recirculation 175, and the downstream receiving system (e.g., system 124 or system 134), enabling controlled fluid flow through the core sample 111 during NMR or MRI measurements.

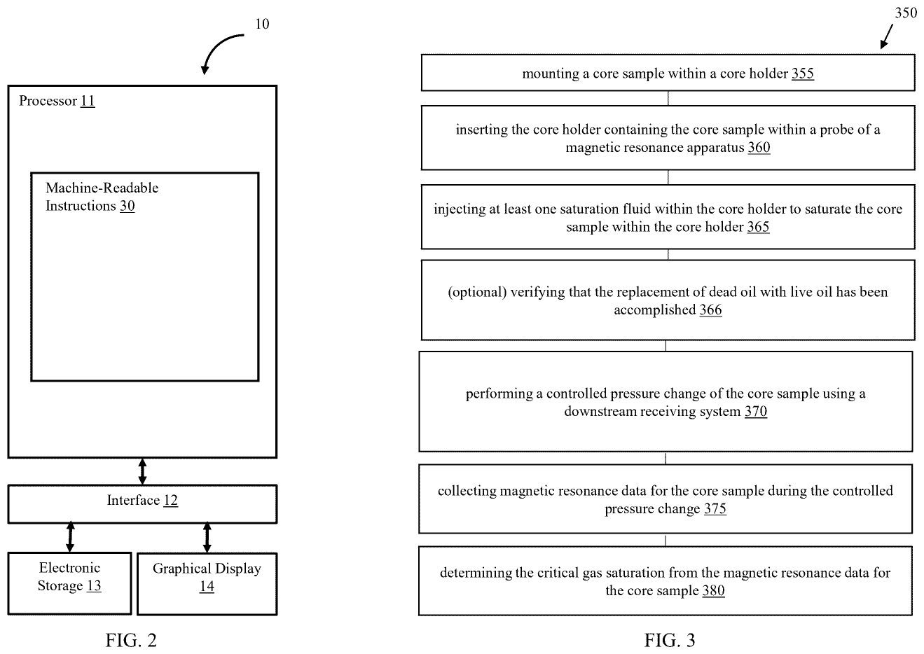

The computer 165 and other electronic components of the system 100 may be implemented by a system and/or in a system, such as a system 10 shown in FIG. 2. The system 10 may include one or more of a processor 11, an interface 12 (e.g., bus, wireless interface), an electronic storage 13, a graphical display 14, and/or other components.

The electronic storage 13 may be configured to include any electronic storage medium that electronically stores information. The electronic storage 13 may store software algorithms, information determined by the processor 11, information received remotely, and/or other information that enables the system 10 to function properly. For example, the electronic storage 13 may store information relating to input, and/or other information. For example, the electronic storage 13 may store information relating to output, and/or other information. The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may include one or more non-transitory computer readable storage medium storing one or more programs. The electronic storage 13 may be a separate component within the system 10, or the electronic storage 13 may be provided integrally with one or more other components of the system 10 (e.g., the processor 11). Although the electronic storage 13 is shown in FIG. 2 as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

The graphical display 14 may refer to an electronic device that provides visual presentation of information. The graphical display 14 may include a color display and/or a non-color display. The graphical display 14 may be configured to visually present information. The graphical display 14 may present information using/within one or more graphical user interfaces. For example, the graphical display 14 may present information relating to intermediate & final results, and/or other information.

The processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 30 to facilitate performing a test on a core sample, such as performing a test of determining of critical gas saturation for the core sample.

It should be appreciated that although computer program components are illustrated in FIG. 2 as being co-located within a single processing unit, one or more of computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 30, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 11 may be configured to execute one or more additional computer program components that may perform some or all of the functionality attributed to one or more of computer program components described herein.

Many modifications and variations are possible in view of the above teachings. The embodiments and examples provided herein are not meant to limit the scope of the invention.

Process 350 in FIG. 3 illustrates one embodiment of a method of determining critical gas saturation for a core sample. The system 100, as well as the components thereof, illustrated in FIGS. 1A-FIG. 2 may be utilized with the process 350. As explained herein, it is oftentimes challenging to determine critical gas saturation for some types of core samples, such as unconventional shale core samples (e.g., unconventional shales producing hydrocarbons) and tight carbonate core samples. For example, mass balance may be difficult due to the small pore volume of these types of core samples. Moreover, CT (or microCT) imaging of these types of core samples may be challenging due to resolution constraints. In contrast, as provided in this document, integration of NMR and/or MRI with laboratory-scale pressure depletion may increase the accuracy of estimates of critical gas saturations for core samples, such as unconventional shale core samples and tight carbonate core samples. The accuracy of estimates of critical gas saturations may even be increased for core samples that are not unconventional shale core samples and not tight carbonate core samples.

For ease of understanding, a running example is referenced herein for an unconventional shale core sample. The running example relied on a magnetic resonance apparatus with MRI (i.e., 42 MHz imager), a probe, a gradient system, and a zirconia coreholder that is NMR and/or MRI compatible, allowing for in-situ determination of saturation (e.g., critical gas saturation) during displacement processes using MRI and/or NMR techniques. Experiments were performed over pressure ranging from 200 psi to 3,000 psi and room temperature (e.g., 68° F.-77° F.) to 210° F. The embodiments and examples provided herein are not meant to limit the scope of the invention.

At step 355, the process 350 comprises mounting a core sample within a core holder. For instance, the core sample 111 of interest may be selected and mounted in the core holder 110 by a user. In one embodiment, the core sample 111 is an unconventional shale core sample (e.g., an unconventional shale core sample having a permeability in a range of from 0.000001 mD to 25 mD). In one embodiment, the core sample 111 is a tight carbonate core sample (e.g., a tight carbonate core sample having a permeability in a range of from 0.000001 mD to 25 mD). In one embodiment, the core sample 111 has a permeability in a range of from 0.000001 mD to 25 mD.

At step 360, the process 350 comprises inserting the core holder containing the core sample within a probe of a magnetic resonance apparatus. For instance, the core holder 110 containing the core sample 111 is inserted within the probe 109 of the magnetic resonance apparatus 105. The probe 109 is a RF probe configured to control temperature within the core holder 110. The probe 109 is configured to be within the gradient system 108 for imaging the core sample 111. The gradient system 108 may comprise at least one gradient coil, such as three gradient coils for MRI. The gradient system 108 may not have any gradient coils for NMR. If the gradient system 108 comprises one or more gradient coils, then the gradient system 108 may also comprise a cooling system for cooling. The core holder 110 is compatible with MRI, compatible with NMR, or compatible with both MRI and NMR to enable operation within the magnetic resonance apparatus 105, which includes MRI, NMR, or both MRI and NMR.

At step 365, the process 350 comprises injecting at least one saturation fluid within the core holder to saturate the core sample within the core holder. For instance, the core sample 111 is saturated with a first saturation fluid that is a dead oil (e.g., hydrocarbon liquid void of dissolved gas), such as decane or stock tank oil, using the first source accumulator 115a, the syringe pump 120, and the on-board controller 121. Next, the core sample 111 is saturated with a second saturation fluid that is a live oil (e.g., hydrocarbon liquid with dissolved gas) using the second source accumulator 115b, the syringe pump 120, and the on-board controller 121. This second step is undertaken to displace the dead oil with the live oil. Displacement may be performed at least 500 psi above the bubble point to minimize the chance of trapped gas or bubble formation.

Optionally, the process 350 may comprise a step 366 of verifying that the replacement of dead oil with live oil has been accomplished. For instance, this optional step includes using NMR signal intensity changes and measurement of producing GOR (Rₚ), if option #2 of the downstream receiving system 134 has been used. Upon replacement of dead oil with live oil, the initial signal intensity (Mₒ) of the oil phase generated by a NMR experiment (i.e., a Carr-Purcell-Meiboom-Gill (CPMG) sequence) is expected to change in proportion to the ratio of the hydrogen indices of the live and dead oils (Equation 301). Similarly, after displacement of the dead oil, the Rₚ, the ratio of the gas (q_{g}) and oil (qₒ) producing flow rates (Equation 302) will approach the solution GOR (Rₛ) of the live oil. The solution GOR (Rₛ) of the live oil can be measured in the lab using a gasometer.

In optional Equation 301 below, HI_{Live} refers to a hydrogen index of live oil, M₀_{_{Live}} refers to an initial signal intensity of live oil, and M₀_{_{Dead}} refers to an initial signal intensity of dead oil. In optional Equation 302 below, q_{g} refers to a producing gas flow rate, qₒ refers to a producing oil flow rate, and Rₚ refers to a producing gas oil ratio.

$$\frac{{M}_{{0}_{L i v e}}}{{HI}_{L i v e}} = {M}_{{0}_{Dead}} \qquad ( Equation 301 )$$

$${R}_{p} = \frac{{q}_{g}}{{q}_{o}} \qquad ( Equation 302 )$$

At step 370, the process 350 comprises performing a controlled pressure change (e.g., controlled pressure depletion) of the core sample using a downstream receiving system (e.g., Option 1 accumulator of option 1 or a gas/oil separator of Option 2). For instance, the downstream receiving system 124, which is referred to herein as Option #1, may be utilized to initiate the controlled pressure change of the core sample 111. After establishing the initial live oil saturation, pressure depletion may begin via controlled pressure decline (Option #1) using the receiving accumulator 125, the syringe pump 130, and the on-board controller 131.

Alternatively, the downstream receiving system 134, which is referred to herein as option #2, may be utilized to initiate the controlled pressure change of the core sample 111. After establishing the initial live oil saturation, pressure depletion may begin through the back pressure 135 and into a gas/oil separator setup illustrated in the downstream receiving system 134.

Option #1 allows for easier control of the pressure decline. Effluent fluid samples may be collected using Option #2 allowing for a material balance to be completed for samples with larger pore volume. For samples with small pore volume, dead volume corrections may be utilized to approximate a material balance.

At step 375, the process 350 comprises collecting magnetic resonance data for the core sample during the controlled pressure change. The magnetic resonance data may comprise T₁-T₂ relaxation distributions, spin echo data, T₂*, diffusion data, diffusion-T₂ maps, or any combination thereof. For instance, the gradient system 108 may be utilized for imaging the core sample 111. Steps 370 and 375 may begin almost simultaneously in one embodiment. Steps 370 and 375 may occur together in one embodiment.

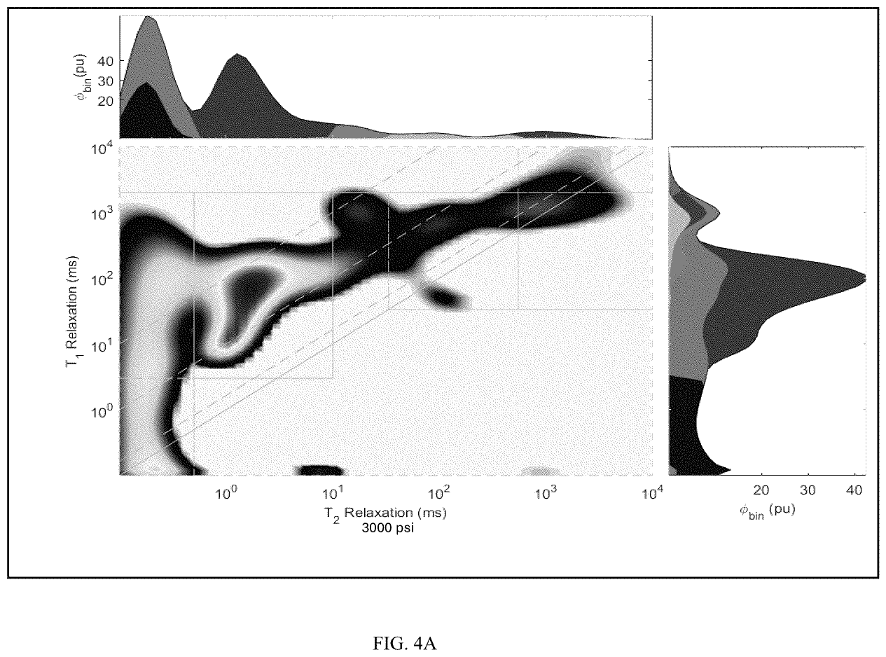

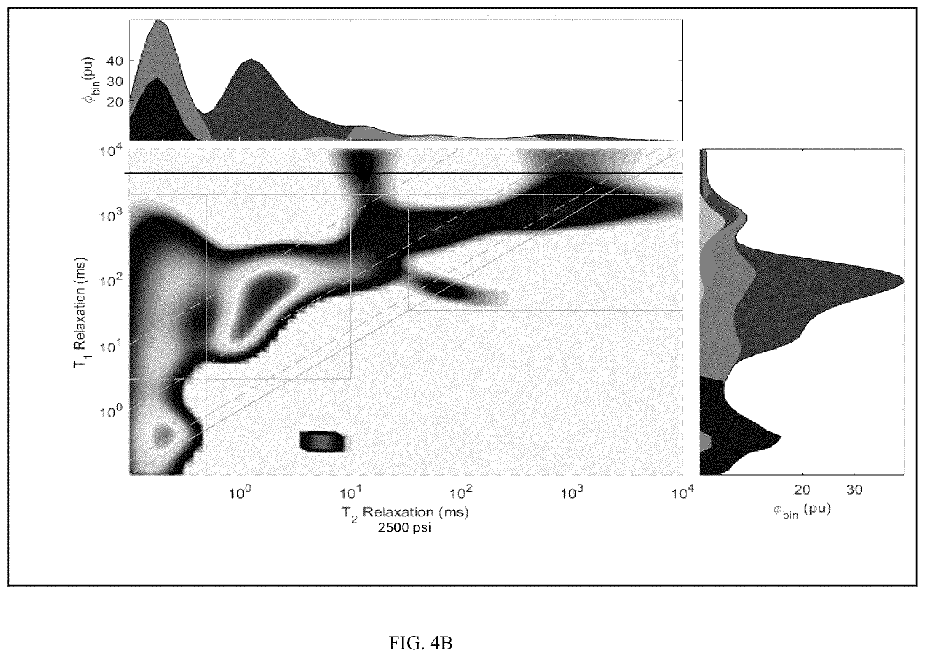

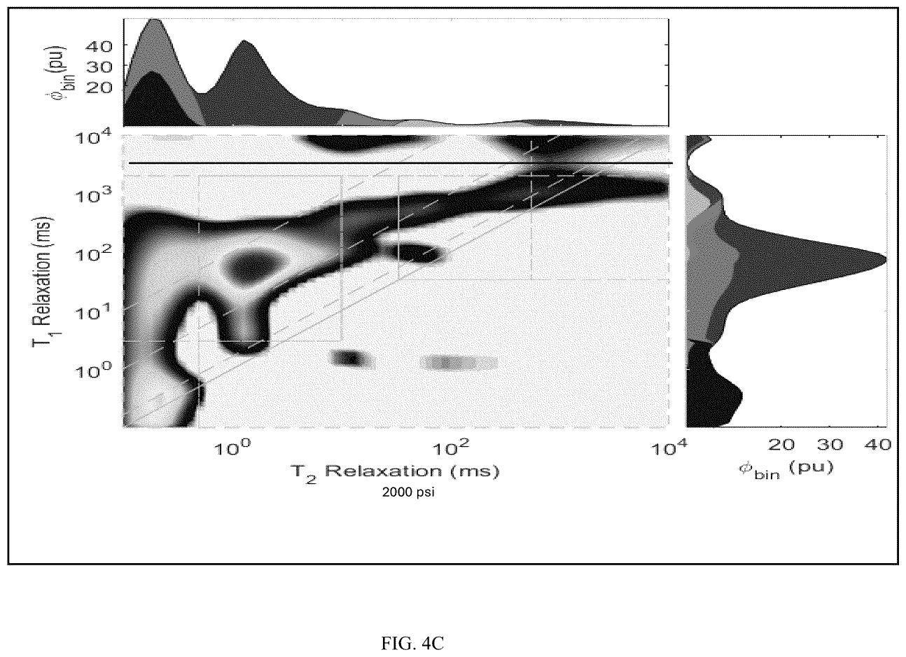

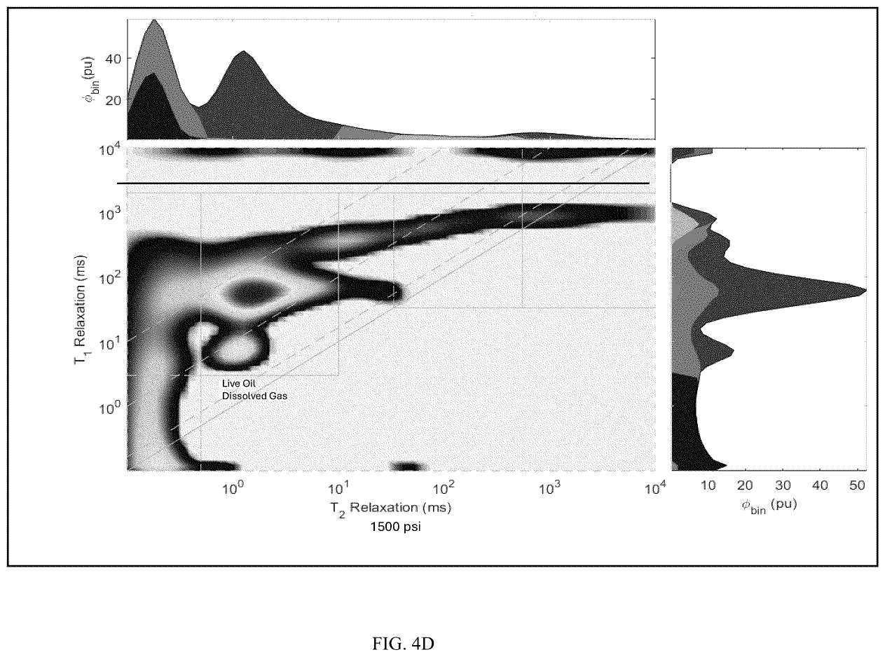

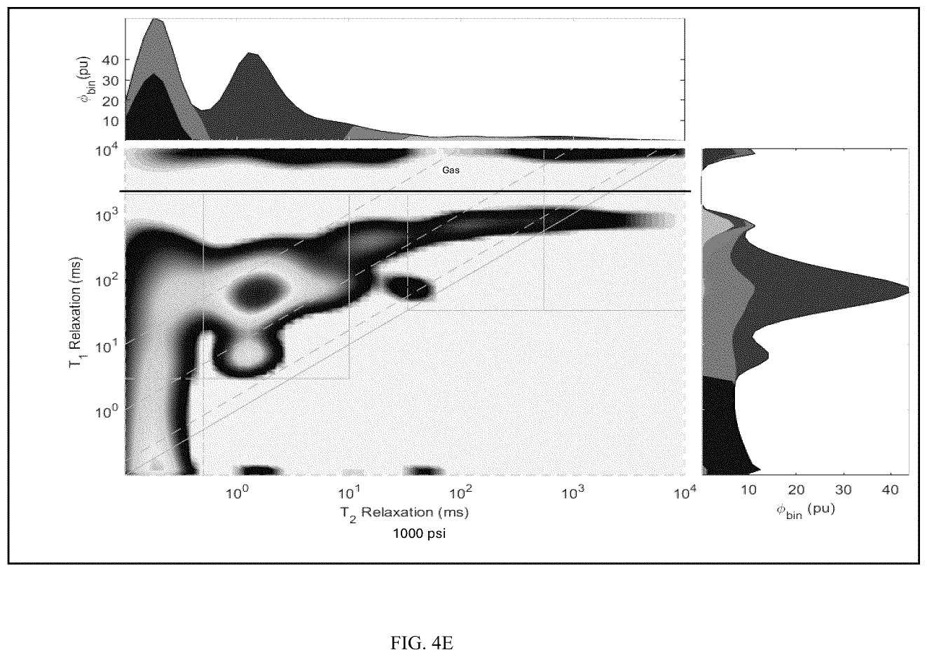

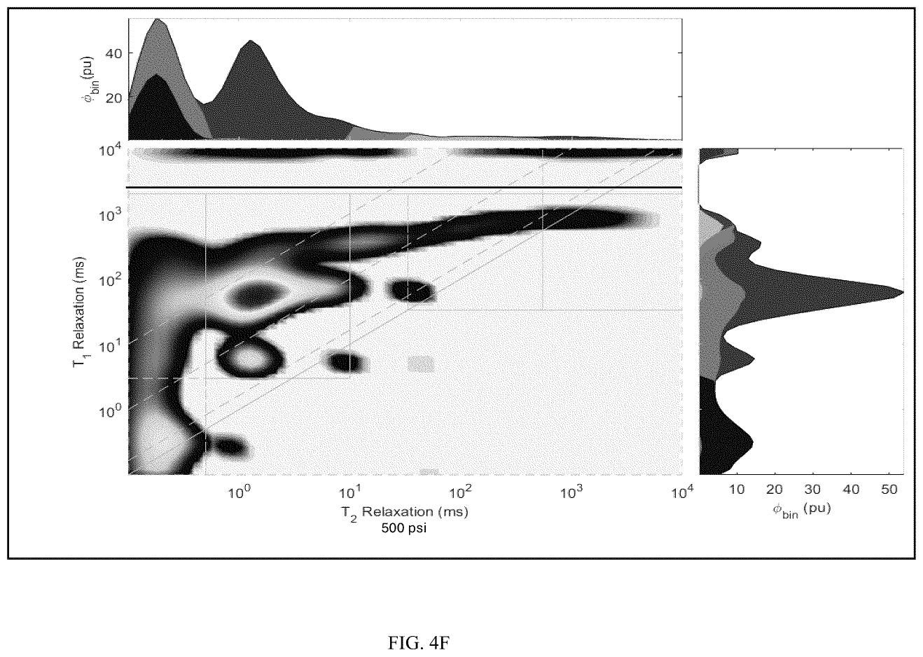

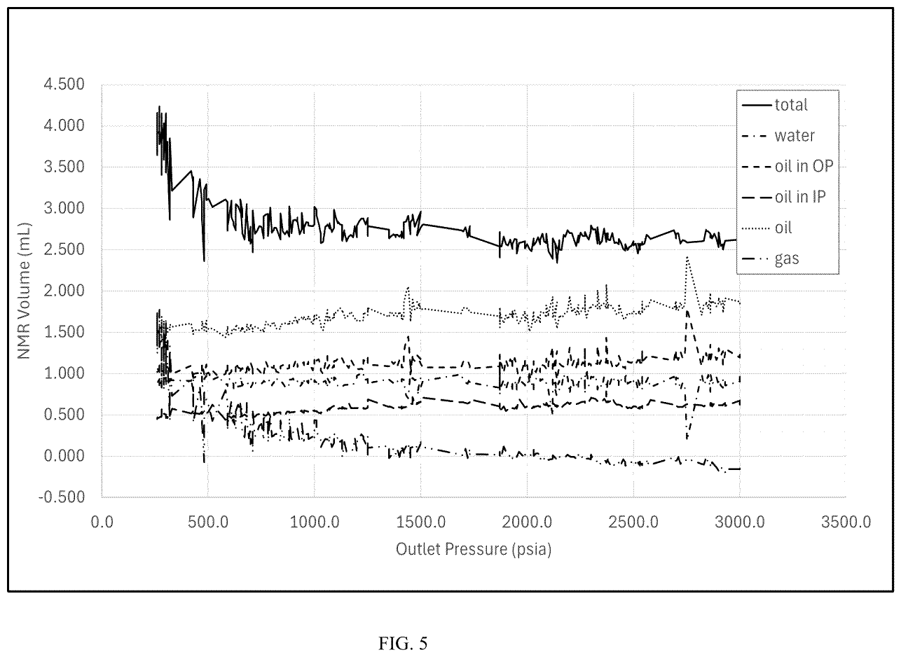

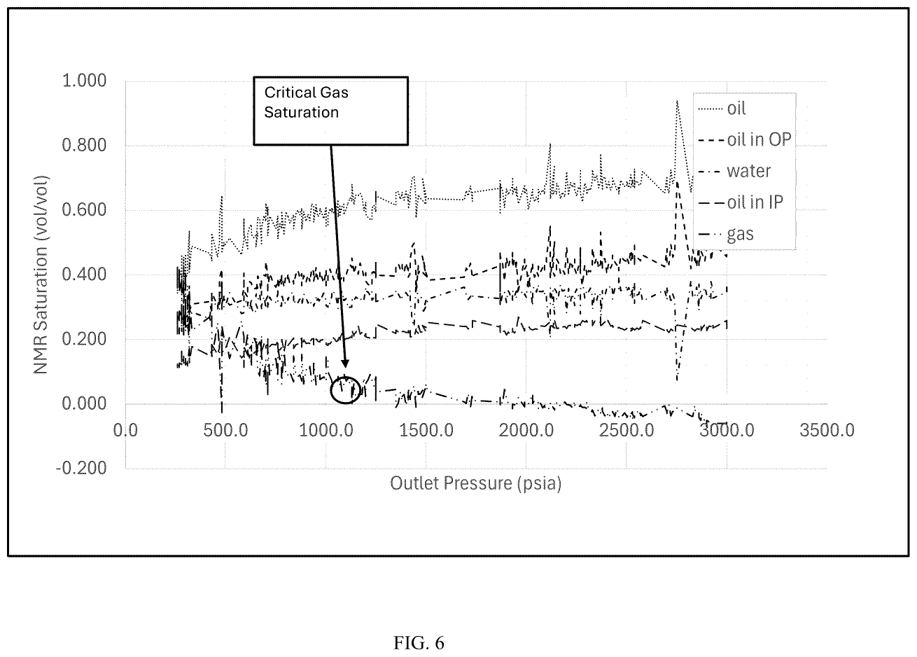

NMR (and/or MRI) measurements may be performed throughout the controlled pressure change (e.g., throughout the controlled pressure depletion). FIGS. 4A-4F illustrate T₁-T₂ relaxation time distributions collected throughout the controlled pressure depletion the unconventional share core sample in the running example herein. FIG. 6 also illustrates magnetic resonance data collected for the unconventional share core sample in the running example herein. Other NMR (and/or MRI) measurements and properties may include Mo, T₂*, T₁, T₂, D, D-T₂, spin-echo and/or Sprite Imaging. In addition to NMR (and/or MRI) measurements, pressure and rate data can be collected from equipment, such as, but not limited to, pressure gauges (not shown in figures), pumps such as the syringe pumps 130 and 155, cylinders such as the graduated cylinder 140, and receiving tanks such as the receiving tank 150. The magnetic resonance data may be recorded in the data acquisition and control system 160, the computer 165, or both.

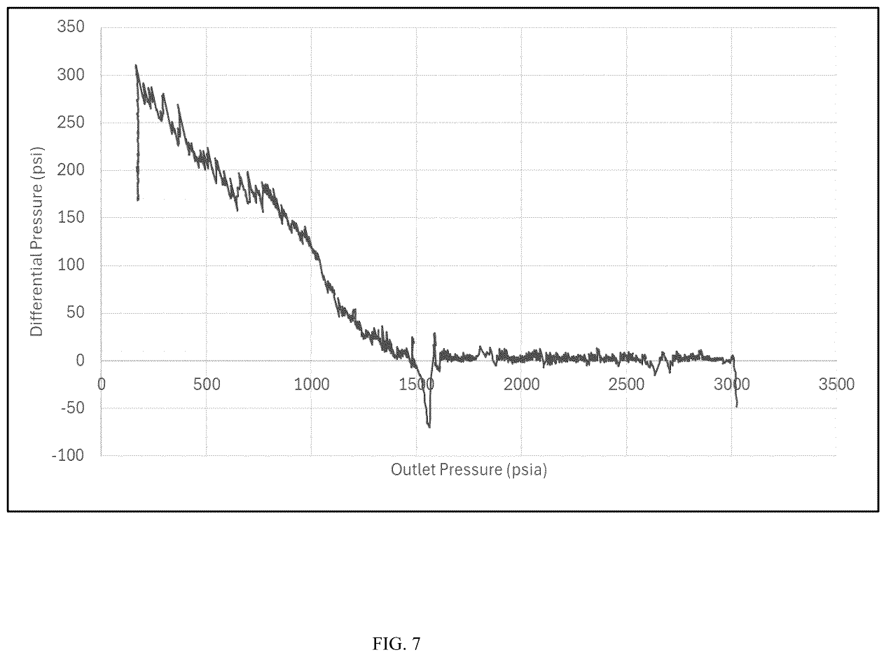

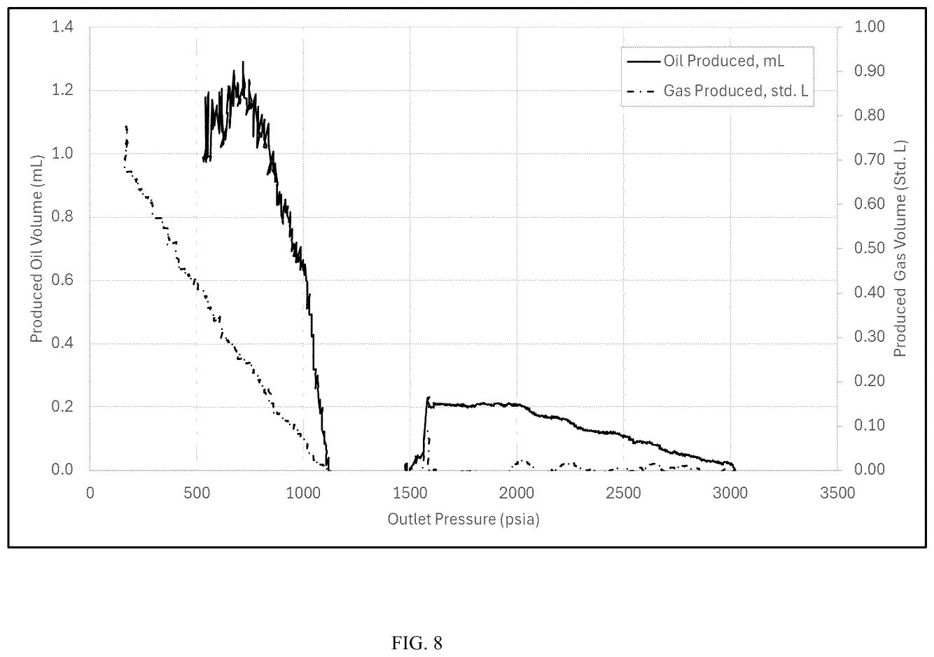

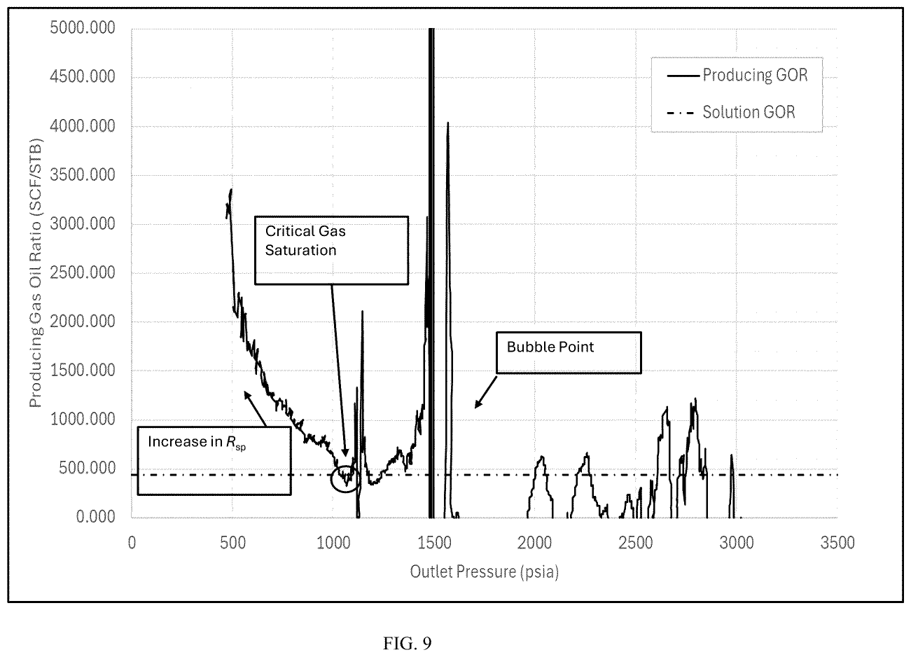

At step 380, the process 350 comprises determining the critical gas saturation from the magnetic resonance data for the core sample. Two methodologies (i.e., Methodology A and Methodology B) are provided herein for determining the critical gas saturation of the core sample. If a unique peak corresponding to disconnected gas phase is encountered, then Methodology A may be utilized. Methodology A comprises utilizing Equations 305, 306, and 308. If a unique peak corresponding to disconnected gas phase is not encountered, then Methodology B may be utilized. Methodology B comprises utilizing Equation 308 and supplemental information (e.g., supplemental information from pressure transducers such as pressure transducers 160, 161, and/or 162 (if downstream receiving system 134 is utilized (Option #2)) to utilize mass balance Equation 309 to identify when gas starts to move out. FIG. 7, FIG. 8, and FIG. 9 for the unconventional shales core sample in the running example relate to Methodology B, and these may be utilized to determine when critical gas saturation has passed.

Turning to Methodology A, upon completion of the coreflood, analysis of NMR data yields identification of oil, gas, and potentially disconnected gas phases. From a T₁-T₂ plot, phase volumes can be calculated using Equation 305.

In Equation 305 below, Vₖ is volume of phase k, c is a calibration constant relating machine units to volume, HIₖ is hydrogen index of phase k, f(T₁, T₂) is T₁-T₂ distribution, and sets A and B define portions of the T₁-T₂ distribution corresponding to phase k. Additionally, in Equation 306 below, Vₖ is volume of phase k, and PV is pore volume of core sample. The pore volume PV of the core sample is assumed to remain constant throughout the pressure depletion. The result of Equation 305 will be used in Equation 306. The results of Equation 305 and Equation 306 will be utilized for Equation 308 below.

$${V}_{k} = \frac{c}{{HI}_{k}} {Σ}_{i ∈ A} {Σ}_{j ∈ B} f ( {T}_{{1}_{i}} , {T}_{{2}_{j}} ) \qquad ( Equation 305 )$$

$$PV = {ΣV}_{k} \qquad ( Equation 306 )$$

NMR is sensitive to the fluid saturating the porous media. As the pressure is depleted, a corresponding change will appear in the collected NMR data. As the molar density of the fluid decreases, the total magnetization will also decrease. As pressure is decreased, the viscosity of the live oil reaches a minimum producing a shift in the T₁-T₂ signal to longer times. Additionally, as gas is produced, total NMR signal decreases proportionally to HI_{g}V_{g}. First, a disconnected gas phase is produced in the porous media, which manifest with high T₁/T₂ ratio indicating that it is trapped. As depletion in the core sample continues, the trapped gas becomes connected and starts to flow, and the NMR peak with the high T₁/T₂ ratio indicating the trapped phase disappears. Regions on the T₁-T₂ can be identified for each phase. Volumes, and subsequently saturation, can be determined using the above relationship. NMR volumes may be calculated from the core sample. These volumes can readily be converted to saturation using Equation 308.

In Equation 308 below, Sₖ is saturation of phase k, Vₖ is volume of phase k, and PV is pore volume of core sample. The results of Equation 305 and Equation 306 will be utilized for Equation 308 below.

$${S}_{k} = \frac{{V}_{k}}{P V} \qquad ( Equation 308 )$$

Critical gas saturation (S_{gc}) is defined as the minimum volume fraction at which a disconnected gas phase becomes connected within a porous medium and becomes mobile. Utilizing NMR, identification of a disconnected gas phase prior to its mobilization is possible. Once the gas has mobilized and the disconnected gas peak is no longer present, the critical gas saturation has been reached. Determination can be done by tracking these saturations vs pressure depletion (i.e., saturation of the trapped gas phase increase steadily, and then drops to zero). This point corresponds to the critical gas saturation.

Turning to Methodology B, for some core samples, clear resolution of a disconnected gas phase is not evident (FIGS. 4A-4F). In this harder scenario, first, NMR volumes may be calculated with the Equation 305. FIG. 5 illustrates NMR volumes calculated from the controlled pressure depletion for the unconventional shale core sample in the running example depicted in FIGS. 4A-4F.

Second, the NMR volumes may be converted to saturations using equation 308 above, see FIG. 6.

Third, NMR data can be supplemented with an array of supplemental data collected during the coreflood, such as, but not limited to, inlet and outlet pressure, differential pressure, fluid and gas volumes produced, core sample temperature, or any combination thereof. Some of this supplemental data may be from pressure transducers such as pressure transducers 160, 161, and/or 162 (if downstream receiving system 134 is utilized (Option #2)).

Fourth, this supplemental data can be used to perform a material balance calculation (Equation 309) for determining critical gas saturation. FIG. 9 demonstrates the differential pressure during the controlled pressure depletion depicted in FIGS. 4A-4F and Equation 306. Similarly, FIG. 8 illustrates the produced oil and gas volumes for the same experiment (utilizing Option #2). FIG. 9 depicts estimates of producing GOR using volumes of collected fluids.

In Equation 309 below, Nis initial volume of oil in place, Nₚ is volume of oil produced, Bₒ and B_{g} are oil and gas formation volume factors, respectively, Rₛ and Rₚ are solution and producing gas oil ratio, respectively, and subscript i denotes initial conditions.

$${N}_{p} ( {B}_{o} + ( {R}_{p} - {R}_{S} ) {B}_{g} ) = N ( ( {B}_{o} - {B}_{o i} ) + ( {R}_{S i} - {R}_{S} ) {B}_{g} ) \qquad ( Equation 309 )$$

Regarding Methodology B, in situations where a clear, distinguishable signal identifying a disconnected gas phases is not present, supplemental data aids in determining the critical gas saturation. NMR or MRI allows for the determination of saturation (FIG. 5). Indication of gas flow, and therefore the critical gas saturation, is signaled by increased gas production (FIG. 9) and changes in pressure drop (FIG. 7). For the depletion study in the unconventional shale core sample, S_{gc} was estimated to be 0.08. Of note, critical gas saturation was estimated to be a single number, but a critical gas saturation curve could be generated in other embodiments.

Many modifications and variations are possible in view of the above teachings. The embodiments and examples provided herein are not meant to limit the scope of the invention. For instance, other tests may be performed in some embodiments including measuring saturation and relative permeability, performing a test that allow for the study of displacement mechanisms/Enhanced Oil Recovery (EOR), performing an external gas drive, etc.

While particular embodiments are described above, it will be understood it is not intended to limit the invention to these particular embodiments. On the contrary, the invention includes alternatives, modifications and equivalents that are within the spirit and scope of the appended claims. Numerous specific details are set forth in order to provide a thorough understanding of the subject matter presented herein. But it will be apparent to one of ordinary skill in the art that the subject matter may be practiced without these specific details. In other instances, well-known methods, procedures, components, and circuits have not been described in detail so as not to unnecessarily obscure aspects of the embodiments.

The terminology used in the description of the invention herein is for the purpose of describing particular embodiments only and is not intended to be limiting of the invention. As used in the description of the invention and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, operations, elements, and/or components, but do not preclude the presence or addition of one or more other features, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

As used herein, the use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent of the given numeric value provided such a deviation does not alter the end function or result of the value. Therefore, a value of about 1% can be construed to be a range from 0.9% to 1.1%. Furthermore, a range may be construed to include the start and the end of the range. For example, a range of 10% to 20% (i.e., range of 10%-20%) includes 10% and also includes 20%, and includes percentages in between 10% and 20%, unless explicitly stated otherwise herein. Similarly, a range of between 10% and 20% (i.e., range between 10%-20%) includes 10% and also includes 20%, and includes percentages in between 10% and 20%, unless explicitly stated otherwise herein.

As used herein, “obtaining” data or information may include one or more of accessing, acquiring, analyzing, determining, examining, identifying, loading, locating, opening, receiving, retrieving, reviewing, selecting, storing, and/or otherwise obtaining the data or information.

As used herein, a “reservoir” refers to a subsurface rock matrix in which a wellbore may be drilled. For example, a reservoir refers to a body of rock that is sufficiently distinctive and continuous such that it can be mapped. A reservoir stores resources, such as hydrocarbons, in its pore space. Reservoirs may vary in geologic features, such as, but not limited to, porosity, mineralogy, geomechanics, permeability, fluid saturation, presence of fractures, geologic structure (e.g., folds, manipulated by tectonic processes), thermal maturity, diagenetic alterations, etc. As used herein, in some embodiments, a reservoir may have a permeability of nanodarcy permeability to millidarcy permeability. The term reservoir may sometimes be used synonymously with the term “subsurface reservoir” or “subsurface formation” or “subsurface formation” or “subsurface volume of interest” or “subterranean formation” or “subsurface” or “formation” or the like. Indeed, the terms “hydrocarbon”, “reservoir”, and the like are not limited to any description or configuration described herein.

As used herein, an “unconventional reservoir” or “unconventional formation” generally requires intervention in order to recover hydrocarbons at economic flow rates or volumes. For example, an unconventional formation includes reservoirs having an unconventional microstructure in which fractures are used to recover hydrocarbons from the reservoir at sufficient flow rates or volumes (e.g., an unconventional reservoir generally needs to be fractured under pressure or have naturally occurring fractures in order to recover hydrocarbons from the reservoir at sufficient flow rates or volumes).

In some embodiments, the unconventional formation can include a reservoir having a permeability of less than 25 millidarcy (mD) (e.g., 20 mD or less, 15 mD or less, 10 mD or less, 5 mD or less, 1 mD or less, 0.5 mD or less, 0.1 mD or less, 0.05 mD or less, 0.01 mD or less, 0.005 mD or less, 0.001 mD or less, 0.0005 mD or less, 0.0001 mD or less, 0.00005 mD or less, 0.00001 mD or less, 0.000005 mD or less, 0.000001 mD or less, or less). In some embodiments, the unconventional formation can include a reservoir having a permeability of at least 0.000001 mD (e.g., at least 0.000005 mD, at least 0.00001 mD, 0.00005 mD, at least 0.0001 mD, 0.0005 mD, 0.001 mD, at least 0.005 mD, at least 0.01 mD, at least 0.05 mD, at least 0.1 mD, at least 0.5 mD, at least 1 mD, at least 5 mD, at least 10 mD, at least 15 mD, or at least 20 mD).

The unconventional formation can include a reservoir having a permeability ranging from any of the minimum values described above to any of the maximum values described above. For example, in some embodiments, the unconventional formation can include a reservoir having a permeability of from 0.000001 mD to 25 mD (e.g., from 0.001 mD to 25 mD, from 0.001 mD to 10 mD, from 0.01 mD to 10 mD, from 0.1 mD to 10 mD, from 0.001 mD to 5 mD, from 0.01 mD to 5 mD, or from 0.1 mD to 5 mD). The permeability of a particular formation can be determined by averaging measured permeability values from a series of representative core samples obtained from the formation. The formation may also be divided up into one or more hydrocarbon zones, and hydrocarbons can be produced from each desired hydrocarbon zone.

As used herein, it is understood that when combinations, subsets, groups, etc. of elements are disclosed (e.g., combinations of components in a composition, or combinations of steps in a method), that while specific reference of each of the various individual and collective combinations and permutations of these elements may not be explicitly disclosed, each is specifically contemplated and described herein. By way of example, if an item is described herein as including a component of type A, a component of type B, a component of type C, or any combination thereof, it is understood that this phrase describes all of the various individual and collective combinations and permutations of these components. For example, in some embodiments, the item described by this phrase could include only a component of type A. In some embodiments, the item described by this phrase could include only a component of type B. In some embodiments, the item described by this phrase could include only a component of type C. In some embodiments, the item described by this phrase could include a component of type A and a component of type B. In some embodiments, the item described by this phrase could include a component of type A and a component of type C. In some embodiments, the item described by this phrase could include a component of type B and a component of type C. In some embodiments, the item described by this phrase could include a component of type A, a component of type B, and a component of type C. In some embodiments, the item described by this phrase could include two or more components of type A (e.g., A1 and A2). In some embodiments, the item described by this phrase could include two or more components of type B (e.g., B1 and B2). In some embodiments, the item described by this phrase could include two or more components of type C (e.g., C1 and C2). In some embodiments, the item described by this phrase could include two or more of a first component (e.g., two or more components of type A (A1 and A2)), optionally one or more of a second component (e.g., optionally one or more components of type B), and optionally one or more of a third component (e.g., optionally one or more components of type C). In some embodiments, the item described by this phrase could include two or more of a first component (e.g., two or more components of type B (B1 and B2)), optionally one or more of a second component (e.g., optionally one or more components of type A), and optionally one or more of a third component (e.g., optionally one or more components of type C). In some embodiments, the item described by this phrase could include two or more of a first component (e.g., two or more components of type C (C1 and C2)), optionally one or more of a second component (e.g., optionally one or more components of type A), and optionally one or more of a third component (e.g., optionally one or more components of type B).

Unless defined otherwise, all technical and scientific terms used herein have the same meanings as commonly understood by one of skill in the art to which the disclosed invention belongs. All citations referred herein are expressly incorporated by reference.

Although some of the various drawings illustrate a number of logical stages in a particular order, stages that are not order dependent may be reordered and other stages may be combined or broken out. While some reordering or other groupings are specifically mentioned, others will be obvious to those of ordinary skill in the art and so do not present an exhaustive list of alternatives. Moreover, it should be recognized that the stages could be implemented in hardware, firmware, software or any combination thereof.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A system of performing a test on a core sample, the system comprising:
a magnetic resonance apparatus comprising a gradient set configured to image a core sample and a probe configured to control a temperature within a core holder, wherein the probe is positioned within the gradient set, and wherein the core holder is positioned within the probe;
the core holder configured to receive the core sample and a saturation fluid, the core holder being compatible with the magnetic resonance apparatus and configured to be positioned within the probe;
an upstream injecting system fluidly coupled to an inlet of the core holder and configured to inject the saturation fluid into the core holder to saturate the core sample; and
a downstream receiving system fluidly coupled to an outlet of the core holder and configured to control a pressure within the core holder and receive at least a portion of the saturation fluid exiting the core holder.

2. The system of claim 1, wherein the magnetic resonance apparatus comprises magnetic resonance imaging (MRI).

3. The system of claim 1, wherein the magnetic resonance apparatus comprises nuclear magnetic resonance (NMR).

4. The system of claim 1, wherein the downstream receiving system comprises:
a receiving accumulator fluidly coupled to the outlet of the core holder and configured to receive the portion of the saturation fluid exiting the core holder;
a syringe pump fluidly coupled to the receiving accumulator and configured to control the receiving accumulator to receive the portion of the saturation fluid exiting the core holder; and
an on-board controller configured to control the syringe pump.

5. The system of claim 1, wherein the downstream receiving system comprises:
a high-pressure back pressure regulator fluidly coupled to the outlet of the core holder and configured to receive the portion of the saturation fluid exiting the core holder;
a cylinder fluidly coupled to the high-pressure back pressure regulator to receive the portion of the saturation fluid exiting the core holder and configured for gas and oil separation, wherein the oil from the portion of the saturation fluid exiting the core holder remains in the cylinder after separation;
a low-pressure back pressure regulator fluidly coupled to the cylinder to receive gas from the portion of the saturation fluid exiting the core holder after separation and configured to control pressure in the cylinder;
a receiving tank fluidly coupled to the low-pressure back pressure regulator to receive the gas from the portion of the saturation fluid exiting the core holder after separation;
a syringe pump fluidly coupled to the high-pressure back pressure regulator and configured to control the coupled the high-pressure back pressure regulator; and
an on-board controller configured to control the syringe pump.

6. The system of claim 1, wherein the downstream receiving system provides pressure within the core holder of from 200 PSI to 10,000 PSI.

7. The system of claim 1, wherein the probe provides a temperature within the core holder of from 68° F. to 300° F.

8. The system of claim 1, further comprising the core sample, wherein the core sample is an unconventional shale core sample.

9. The system of claim 1, further comprising the core sample, wherein the core sample is a tight carbonate core sample.

10. The system of claim 1, further comprising the core sample, wherein the core sample has a permeability in a range of from 0.000001 mD to 25 mD.

11. A method of determining critical gas saturation for a core sample, the method comprising:
(a) mounting a core sample within a core holder in a system, wherein the system comprises:
a magnetic resonance apparatus comprising a gradient set configured to image the core sample and a probe configured to control a temperature within the core holder, wherein the probe is positioned within the gradient set, and wherein the core holder is positioned within the probe;
the core holder configured to receive the core sample and a saturation fluid, the core holder being compatible with the magnetic resonance apparatus and configured to be positioned within the probe;
an upstream injecting system fluidly coupled to an inlet of the core holder and configured to inject the saturation fluid into the core holder to saturate the core sample; and
a downstream receiving system fluidly coupled to an outlet of the core holder and configured to control a pressure within the core holder and receive at least a portion of the saturation fluid exiting the core holder;
(b) inserting the core holder containing the core sample within the probe of the magnetic resonance apparatus;
(c) injecting at least one saturation fluid within the core holder to saturate the core sample within the core holder;
(d) performing a controlled pressure change of the core sample using the downstream receiving system;
(e) collecting magnetic resonance data for the core sample during the controlled pressure change; and
(f) determining the critical gas saturation from the magnetic resonance data for the core sample.

12. The method of claim 11, wherein determining the critical gas saturation from the magnetic resonance data for the core sample comprises utilizing Methodology A, wherein utilizing Methodology A comprises utilizing an equation, wherein the equation is as follows:
$${V}_{k} = \frac{c}{{HI}_{k}} {Σ}_{i ∈ A} {Σ}_{j ∈ B} f ( {T}_{{1}_{i}} , {T}_{{2}_{j}} ) \qquad ( Equation 305 )$$
wherein Vₖ is volume of phase k, c is a calibration constant relating machine units to volume, HIₖ is hydrogen index of phase k, f(T₁, T₂) is T₁-T₂ distribution, and sets A and B define portions of the T₁-T₂ distribution corresponding to phase k.

13. The method of claim 12, wherein determining the critical gas saturation from the magnetic resonance data for the core sample comprises utilizing Methodology A, wherein utilizing Methodology A comprises utilizing an equation, wherein the equation is as follows:
$$PV = {ΣV}_{k} \qquad ( Equation 306 )$$
wherein Vₖ is volume of phase k, and PV is pore volume of the core sample.

14. The method of claim 13, wherein determining the critical gas saturation from the magnetic resonance data for the core sample comprises utilizing Methodology A, wherein utilizing Methodology A comprises utilizing an equation, wherein the equation is as follows:
$${S}_{k} = \frac{{V}_{k}}{P V} \qquad ( Equation 308 )$$
wherein Sₖ is saturation of phase k, Vₖ is volume of phase k, and PV is pore volume of the core sample.

15. The method of claim 11, wherein determining the critical gas saturation from the magnetic resonance data for the core sample comprises utilizing Methodology B, wherein utilizing Methodology B comprises utilizing an equation, wherein the equation is as follows:
$${V}_{k} = \frac{c}{{HI}_{k}} {Σ}_{i ∈ A} {Σ}_{j ∈ B} f ( {T}_{{1}_{i}} , {T}_{{2}_{j}} ) \qquad ( Equation 305 )$$
wherein Vₖ is volume of phase k, c is a calibration constant relating machine units to volume, HIₖ is hydrogen index of phase k, f(T₁, T₂) is T₁-T₂ distribution, and sets A and B define portions of the T₁-T₂ distribution corresponding to phase k.

16. The method of claim 15, wherein determining the critical gas saturation from the magnetic resonance data for the core sample comprises utilizing Methodology B, wherein utilizing Methodology B comprises utilizing an equation, wherein the equation is as follows:
$${S}_{k} = \frac{{V}_{k}}{P V} \qquad ( Equation 308 )$$
wherein Sₖ is saturation of phase k, Vₖ is volume of phase k, and PV is pore volume of the core sample.

17. The method of claim 16, wherein determining the critical gas saturation from the magnetic resonance data for the core sample comprises utilizing Methodology B, wherein utilizing Methodology B comprises obtaining supplemental data to determine material balance for determining the critical gas saturation of the core sample.

18. The method of claim 17, wherein the supplemental data comprises inlet and outlet pressure, differential pressure, fluid and gas volumes produced, core sample temperature, or any combination thereof.

19. The method of claim 17, wherein the supplemental data is obtained from one or more pressure transducers of the system.

20. The method of claim 17, wherein determining the critical gas saturation from the magnetic resonance data for the core sample comprises utilizing Methodology B, wherein utilizing Methodology B comprises utilizing an equation, wherein the equation is as follows:
$${N}_{p} ( {B}_{o} + ( {R}_{p} - {R}_{S} ) {B}_{g} ) = N ( ( {B}_{o} - {B}_{o i} ) + ( {R}_{S i} - {R}_{S} ) {B}_{g} ) \qquad ( Equation 309 )$$
wherein N is initial volume of oil in place, Nₚ is volume of oil produced, Bₒ and B_{g} are oil and gas formation volume factors, respectively, Rₛ and Rₚ are solution and producing gas oil ratio, respectively, and subscript i denotes initial conditions.
